(19) United States
(12) Patent Application Publication
(10) Pub. No.: US 2025/0331165 A1
(43) Pub. Date: Oct. 23, 2025

(54) SEMICONDUCTOR DEVICE HAVING BIT LINE STRUCTURE AND METHOD FOR MANUFACTURING THE SAME

(71) Applicant: NANYA TECHNOLOGY CORPORATION, NEW TAIPEI CITY (TW)

(72) Inventor: CHUN-HENG WU, NEW TAIPEI CITY (TW)

(21) Appl. No.: 18/643,049

(22) Filed: Apr. 23, 2024

(51) Int. Cl. H10B 12/00; H01L 23/532

(52) U.S. Cl. CPC H10B 12/482; H01L 23/5329; H10B 12/485

(57) ABSTRACT

A semiconductor device and a method of manufacturing a semiconductor device are provided. The semiconductor device includes a substrate and a bit line structure disposed over the substrate. The bit line structure includes an insulating spacer structure defining an air spacer. The semiconductor device also includes a sealing layer disposed over the insulating spacer structure to cover the air spacer. The sealing layer includes a carbon-containing material.

### TECHNICAL FIELD

The present disclosure relates to a semiconductor device and a method for manufacturing a semiconductor device, and more particularly, to a bit line structure having an air spacer.

### DISCUSSION OF THE BACKGROUND

In a semiconductor device, a storage node contact may be formed between neighboring bit line structures. In a conventional process, an air gap is typically formed to electrically insulate the adjacent bit line structures from their corresponding storage node contacts.

When the mold layer around the capacitor bottom electrode is partially removed through a wet etching process, the wet etchants may penetrate the bottom of the air gap and erode the adjacent spacers and the storage node contacts. This erosion issue can degrade performance of the semiconductor device, and is a limiting factor that must be addressed to achieve further enhancements in semiconductor device integration.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device. The semiconductor device includes a substrate and a bit line structure disposed over the substrate. The bit line structure includes an insulating spacer structure defining an air spacer. The semiconductor device also includes a sealing layer disposed over the insulating spacer structure to cover the air spacer. The sealing layer includes a carbon-containing material.

Another aspect of the present disclosure provides a semiconductor device. The semiconductor device includes a substrate, a bit line structure disposed over the substrate, and a landing pad disposed over the bit line structure and having a recess region. The semiconductor device also includes a first sealing layer disposed in the recess region. The first sealing layer includes a carbon-containing material.

Another aspect of the present disclosure provides a method of manufacturing a semiconductor device. The method includes forming a landing pad over a bit line structure and forming a recess region in the landing pad. The method also includes removing a portion of the bit line structure and disposing a first sealing layer in the recess region.

The sealing layer is sufficiently resistant to, for example, a wet etch solution, to prevent over-etching and penetration of the bottom of the air gap. For example, the sealing layer can adequately perform its purpose as an etch stop layer in subsequent etching processes. Therefore, the erosion issue can be addressed. The performance and operational reliability of the semiconductor device can also be improved.

The foregoing has outlined rather broadly the features and technical advantages of the present disclosure so that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a schematic cross-sectional view of a semiconductor device in accordance with some embodiments of the present disclosure.

FIG. 1B is an enlarged view of a portion of a semiconductor device in accordance with some embodiments of the present disclosure.

FIG. 2A is a schematic cross-sectional view illustrating one or more stages of a method of manufacturing a semiconductor device in accordance with some embodiments of the present disclosure.

FIG. 2B is a schematic cross-sectional view illustrating one or more stages of a method of manufacturing a semiconductor device in accordance with some embodiments of the present disclosure.

FIG. 2C is a schematic cross-sectional view illustrating one or more stages of a method of manufacturing a semiconductor device in accordance with some embodiments of the present disclosure.

FIG. 2D is a schematic cross-sectional view illustrating one or more stages of a method of manufacturing a semiconductor device in accordance with some embodiments of the present disclosure.

FIG. 2E is a schematic cross-sectional view illustrating one or more stages of a method of manufacturing a semiconductor device in accordance with some embodiments of the present disclosure.

FIG. 2F is a schematic cross-sectional view illustrating one or more stages of a method of manufacturing a semiconductor device in accordance with some embodiments of the present disclosure.

FIG. 2G is a schematic cross-sectional view illustrating one or more stages of a method of manufacturing a semiconductor device in accordance with some embodiments of the present disclosure.

FIG. 2H is a schematic cross-sectional view illustrating one or more stages of a method of manufacturing a semiconductor device in accordance with some embodiments of the present disclosure.

FIG. 2I is a schematic cross-sectional view illustrating one or more stages of a method of manufacturing a semiconductor device in accordance with some embodiments of the present disclosure.

FIG. 2J is a schematic cross-sectional view illustrating one or more stages of a method of manufacturing a semiconductor device in accordance with some embodiments of the present disclosure.

FIG. 2K is a schematic cross-sectional view illustrating one or more stages of a method of manufacturing a semiconductor device in accordance with some embodiments of the present disclosure.

FIG. 3 illustrates a flow chart of a method of manufacturing a semiconductor device in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only, and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

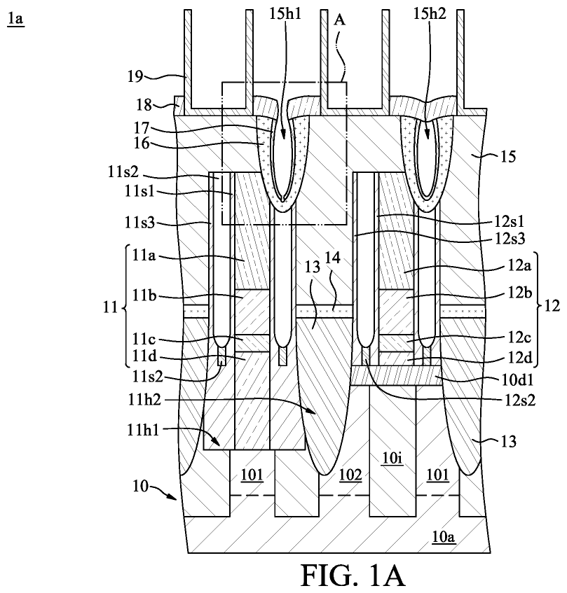

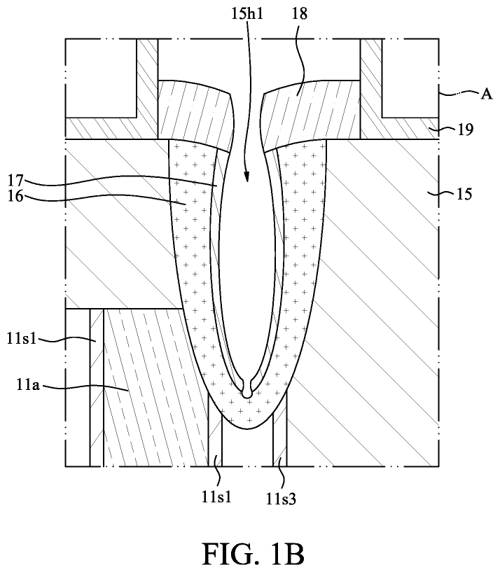

FIG. 1A is a schematic cross-sectional view of a semiconductor device 1a in accordance with some embodiments of the present disclosure. In some embodiments, the semiconductor device 1a may be disposed adjacent to a circuit. For example, the semiconductor device 1a may be disposed adjacent to a memory device such as a dynamic random access memory (DRAM) device or the like.

Referring to FIG. 1A, the semiconductor device 1a may include a substrate 10 and bit line structures 11 and 12. The bit line structures 11 and 12 may be disposed over the substrate 10.

The substrate 10 may include a semiconductor substrate. In some embodiments, the semiconductor material of the substrate 10 may include, for example, silicon (Si) (such as monocrystalline silicon, polysilicon, and amorphous silicon), germanium (Ge), gallium (Ga), and indium (In). In some embodiments, the semiconductor material of the substrate 10 may include a compound semiconductor including silicon germanium (SiGe), silicon carbide (SiC), silicon germanium carbide (SiGeC), gallium arsenide (GaAs), gallium phosphide (GaP), indium arsenide (InAs), indium phosphide (InP), indium antimonide (InSb), or other IV-IV, III-V or II-VI semiconductor materials.

In some embodiments, the substrate 10 may include a bulk semiconductor, a semiconductor-on-insulator (SOI) substrate, a multi-layered substrate, or a gradient substrate. For example, the SOI substrate may include a layer of a semiconductor material formed on an insulator layer. The insulator layer may be, for example, a buried oxide (BOX) layer, a silicon oxide layer, or the like. The insulator layer may be provided on a substrate, typically a silicon or glass substrate. In some embodiments, the substrate 10 may be a wafer, such as a silicon wafer. The substrate 10 may be doped (e.g., with a P-type or an N-type dopant) or undoped.

The substrate 10 may include an active region 10a and a plurality of isolation regions 10i. From a top view, a plurality of the active regions 10a may be defined by the isolation region 10i. For example, a plurality of the active regions 10a may be separated from one another by the isolation region 10i.

The active region 10a and the isolation region 10i may be formed in the substrate 10. In some embodiments, the isolation region 10i may include shallow trench isolation (STI) structures.

A wall oxide, a liner and a gap-fill dielectric may be sequentially formed as the isolation region 10i. The liner may be formed by stacking silicon oxide (SiO₂) and silicon nitride (Si₃N₄). The gap-fill dielectric may include, for example, silicon oxide (SiO₂), silicon nitride (Si₃N₄), a low-k (e.g., having a dielectric constant less than that of silicon oxide, which is about 3.9) dielectric material (e.g., phosphosilicate glass (PSG), borosilicate glass (BSG), boron-doped phosphosilicate glass (BPSG), undoped silicate glass (USG), etc.), the like, or combinations thereof. In another embodiment, in the isolation region 10i, a silicon nitride may be used as the gap-fill dielectric.

The substrate 10 may include a plurality of doped regions, such as doped regions 101 and 102. The doped regions 101 and 102 may be formed in the active region 10a. In some embodiments, the doped regions 101 and 102 may be disposed over or proximal to the top surface of the active region 10a. The doped regions 101 and 102 may be spaced apart from one another by the isolation regions 10i. For example, the doped region 102 may be disposed between the doped regions 101 and spaced apart from the doped regions 101 by the isolation regions 10i.

In some embodiments, the doped regions 101 and 102 may be doped with an N-type dopant such as phosphorus (P), arsenic (As), or antimony (Sb). In some other embodiments, the doped regions 101 and 102 may be doped with a P-type dopant such as boron (B) or indium (In). In some embodiments, the doped regions 101 and 102 may be doped with dopants or impurity ions having the same conductivity types. In some embodiments, the doped regions 101 and 102 may be doped with dopants or impurity ions having different conductivity types.

The bottom surfaces of the doped regions 101 and 102 may be located at a predetermined depth from the top surface of the active region 10a. The doped regions 101 and 102 may be adjacent to sidewalls of the isolation region 10i. The bottom surfaces of the doped regions 101 and 102 may be higher than the bottom surface of the isolation region 10i.

In some embodiments, the doped regions 101 and 102 may be referred to as source/drain regions. In some embodiments, the doped region 101 may include a bit line contact region and may be electrically connected with the bit line structure 11. The doped region 102 may include a storage node contact region and may be electrically connected with a memory element through the storage node contact 13. In some embodiments, the memory element may be a capacitor, and may include a bottom electrode (such as the bottom electrode 19), a top electrode and a dielectric layer therebetween. In other embodiments, the memory element may be a variable resistance pattern capable of switching between two resistance states by an electrical pulse applied to the memory element. For example, the memory element may include a phase change material capable of changing a crystalline state according to an amount of electrical current, such as perovskite compounds, transition metal oxide, magnetic materials, ferromagnetic materials or antiferromagnetic materials.

An interlayer 10d1 may be disposed on the substrate 10. The interlayer 10d1 may be disposed on the top surface of the active region 10a. The interlayer 10d1 may be formed of either a single insulating layer or a plurality of insulating layers. The interlayer 10d1 may include an isolating material or a dielectric material. The interlayer 10d1 may include, for example, silicon oxide (SiO₂), silicon nitride (Si₃N₄) and/or silicon oxynitride.

A recess region 11h1 may be formed in the substrate 10. The bit line structure 11 may be disposed in the recess region 11h1 and contact (such as directly contact) the doped region 101. Therefore, the doped region 101 may include the bit line contact region.

The recess region 11h1 may be formed between the isolation regions 10i. The recess region 11h1 may be formed to expose the doped region 101 between the isolation regions 10i.

The recess region 11h1 may recess into the substrate 10 from the top surface of the active region 10a and/or from the interlayer 10d1. The width of the recess region 11h1 may be greater than the distance between the isolation regions 10i.

The bottom surface of the recess region 11h1 may be positioned higher than the bottom surface of the doped region 101. For example, the recess region 11h1 may not extend beyond the bottom surface of the doped region 101.

A recess region 11h2 may be formed in the substrate 10 to expose the doped region 102. The doped region 102 may contact the storage node contact 13. Therefore, the doped region 102 may include the storage node contact region.

The recess region 11h2 may recess from the top surface of the active region 10a and/or from the interlayer 10d1. The recess region 11h2 may be adjacent to the recess region 11h1.

The storage node contact 13 may penetrate the interlayer 10d1 to contact (such as directly contact) the doped region 102. The bottom surface of the storage node contact 13 may be positioned lower than the bottom surface of the recess region 11h1.

A metal silicide film 14 may be formed on the storage node contact 13. A landing pad 15 may be connected to the storage node contact 13, and the metal silicide film 14 may be formed between the landing pad 15 and the storage node contact 13.

The metal silicide film 14 may include cobalt silicide, nickel silicide, and manganese silicide, titanium silicide, etc.

The landing pad 15 may be disposed between the adjacent bit line structures, such as the bit line structures 11 and 12. The landing pad 15 may be vertically overlapped with the bit line structures 11 and 12. The landing pad 15 may be electrically connected to the storage node contact 13.

The landing pad 15 and the storage node contact 13 may each include a conductive material. The landing pad 15 and the storage node contact 13 may each include a doped semiconductor material (e.g., doped silicon), a metal (e.g., tungsten, titanium, and tantalum), a conductive metal nitride (e.g., titanium nitride, tantalum nitride, and tungsten nitride), and a metal-semiconductor compound (e.g., a metal silicide).

The bit line structure 11 may include a bit line contact 11d and stacked patterns (such as a conductive pattern 11c, a conductive pattern 11b, and a bit line capping pattern 11a).

The bit line contact 11d may be disposed in the recess region 11h1. A portion of the bit line contact 11d may contact (such as directly contact) the doped region 101. A bottom surface of the bit line contact 11d may be positioned lower than the top surface of the active region 10a or lower than the interlayer 10d1. The bit line contact 11d may include a doped polysilicon.

The conductive pattern 11c may include any suitable material, such as titanium (Ti), tantalum (Ta), titanium nitride (TiN), tantalum nitride (TaN), tungsten nitride (W₂N, WN, WN₂), the like, or combinations thereof.

The conductive pattern 11b may include any suitable metal, such as tungsten (W), copper (Cu), ruthenium (Ru), aluminum (Al), gold (Au), cobalt (Co), the like, or combinations thereof.

The bit line capping pattern 11a may include, for example, silicon oxide (SiO₂), silicon nitride (Si₃N₄) and/or silicon oxynitride.

The bit line structure 11 may include an insulating spacer structure. The insulating spacer structure may include spacers 11s1, 11s2, and 11s3 formed on both sidewalls of the bit line structure 11. The spacers 11s1, 11s2, and 11s3 may also be referred to as a first spacer, a second spacer, and a third spacer.

The spacer 11s1 may be disposed between the spacer 11s2 and the sidewalls of the bit line structure 11. For example, the spacer 11s1 may directly contact the sidewalls of the bit line structure 11. The spacer 11s2 may be disposed between the spacer 11s1 and the spacer 11s3. The spacer 11s3 may be the outermost spacer of the bit line structure 11.

The spacer 11s2 may include an oxygen-containing material, such as silicon oxide (SiO₂). The spacer 11s2 may include or define an air spacer in which air is filled. In some embodiments, the spacer 11s2 may include a combination of an oxygen-containing material and an air spacer.

As described herein, a spacer may refer to any structure that electrically insulates one conductive structure from another, while an air spacer or an air gap may refer to an insulating structure in which air, in the absence of other insulating materials, provides electrical insulation.

The spacers 11s1 and 11s3 may each include a nitrogen-containing material, such as silicon nitride (Si₃N₄). The spacers 11s1 and 11s3 may connect to each other.

In some embodiments, an air spacer may be defined by an oxygen-containing material (e.g., at the bottom of the spacer 11s2) and a nitrogen-containing material (the material of the spacers 11s1 and 11s3). For example, the oxygen-containing material may define the bottom of the air spacer and the nitrogen-containing material may define the sidewall of the air spacer.

In some embodiments, the spacer 11s1 may have a first dielectric constant, the spacer 11s2 may have a second dielectric constant, and the spacer 11s3 may have a third dielectric constant.

The first dielectric constant may be equal to the third dielectric constant. The second dielectric constant may be lower than the first dielectric constant. The second dielectric constant may be lower than the third dielectric constant.

For example, the third dielectric constant may be approximately 7.5, and the second dielectric constant may be less than approximately 7.5. For example, the second dielectric constant may be approximately 3.9. For example, the second dielectric constant may range from approximately 1.0 to 3.9.

In some embodiments, the spacer 11s2 may be interposed between the bit line structure 11 and the storage node contact 13. By using a spacer (such as the spacer 11s2) having a low dielectric constant, the parasitic capacitance issue between the bit line structures and/or between the bit line structure and the storage node contact can be further decreased.

In some embodiments, an upper portion of the spacer 11s2 may contact a sealing layer 16. For example, the spacer 11s2 may be closed by or covered by the sealing layer 16. The sealing layer 16 may include a material different from the spacers 11s1, 11s2, and 11s3.

The landing pad 15 may define a recess region 15h1 and a recess region 15h2. The recess region 15h1 may be disposed over or on the insulating spacer structure of the bit line structure 11. The recess region 15h2 may be disposed over or on the insulating spacer structure of the bit line structure 12.

The sealing layer 16 may be disposed in the recess region 15h1. The sealing layer 16 may be disposed along the contour of the recess region 15h1. The sealing layer 16 may not fill up the recess region 15h1.

A sealing layer 17 may be disposed along the contour of the sealing layer 16. The sealing layer 17 may not fill up the recess region 15h1. The sealing layer 16 and the sealing layer 17 may also be referred to as a first sealing layer and a second sealing layer.

The sealing layer 16 and the sealing layer 17 may include different materials. For example, the sealing layer 16 may include a carbon-containing material, such as SiC (silicon carbide), SiOC (silicon oxycarbide), SiCN (silicon carbon nitride), and SiOCN (silicon oxycarbonitride). The sealing layer 17 may each include a nitrogen-containing material, such as silicon nitride (Si₃N₄).

The sealing layer 16 and the sealing layer 17 may define an air gap. The air gap defined by the sealing layer 16 and the sealing layer 17 may be closed by or covered by an interlayer 18. The air gap may be filled by air.

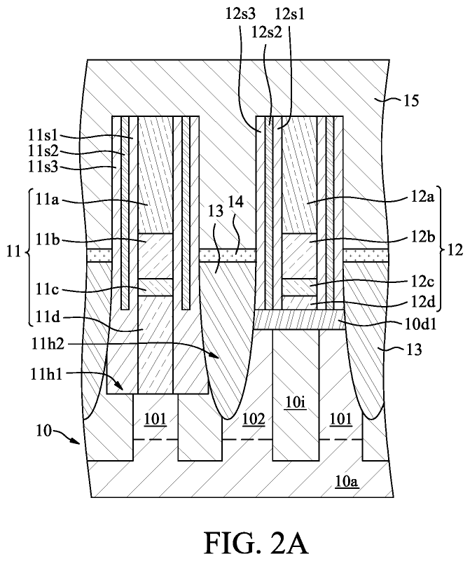

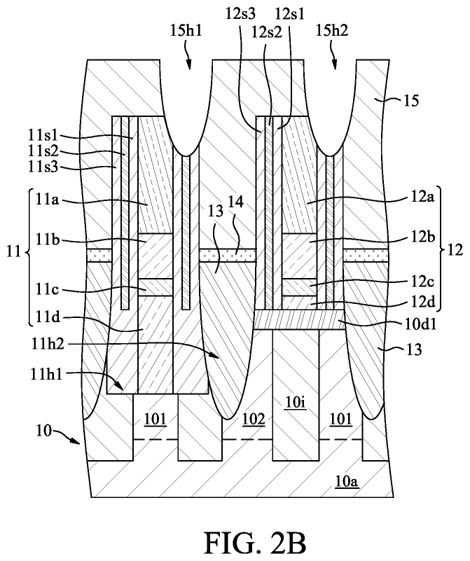

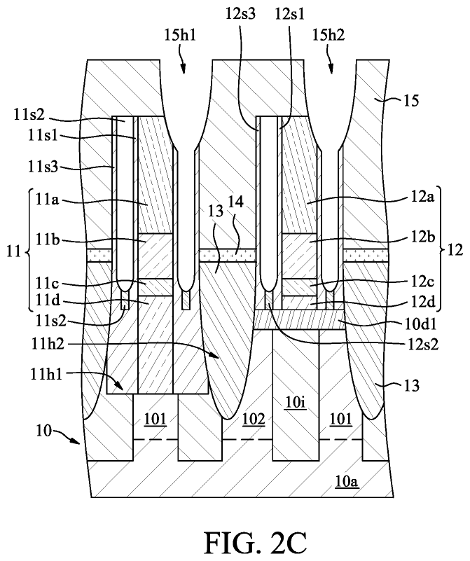

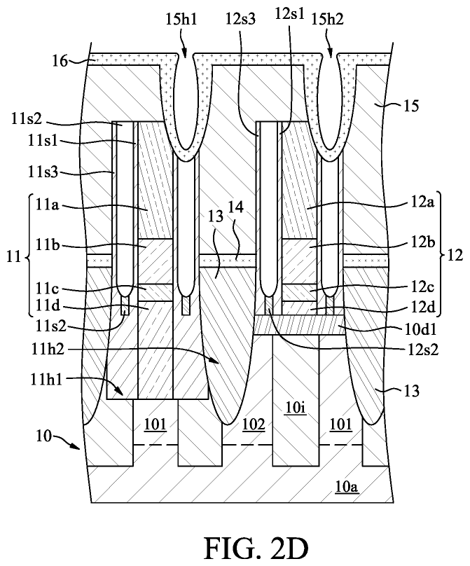

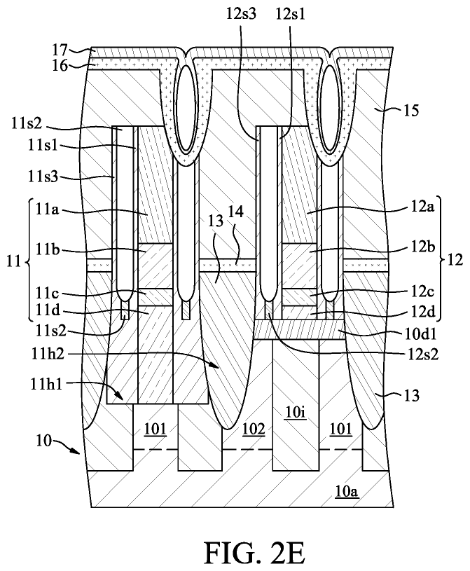

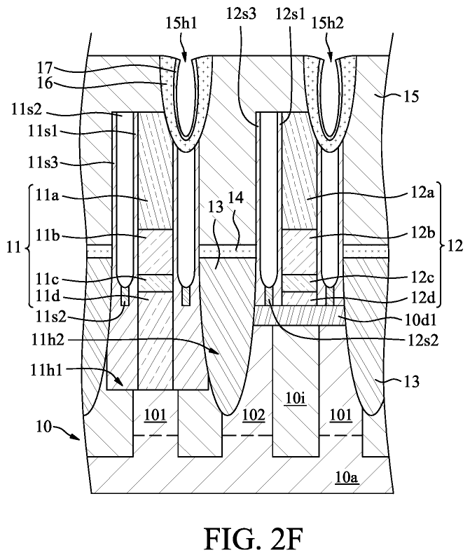

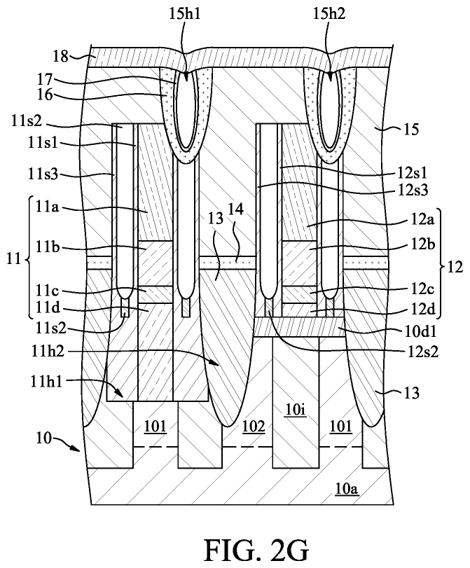

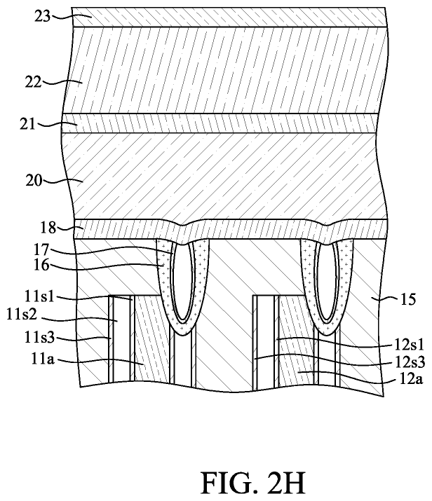

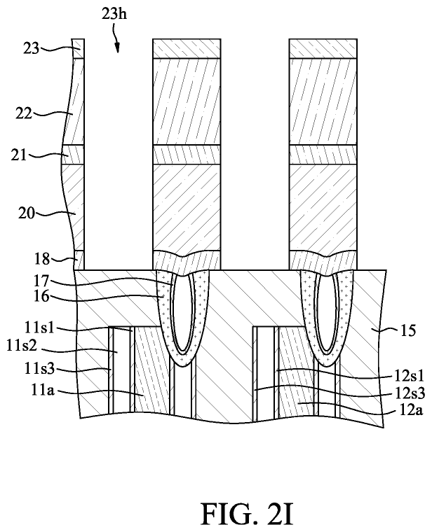

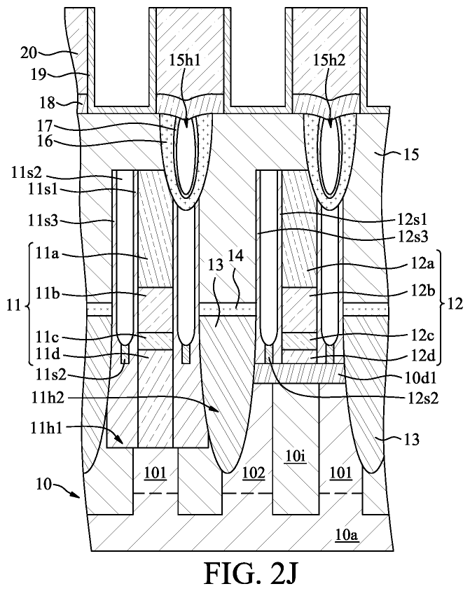

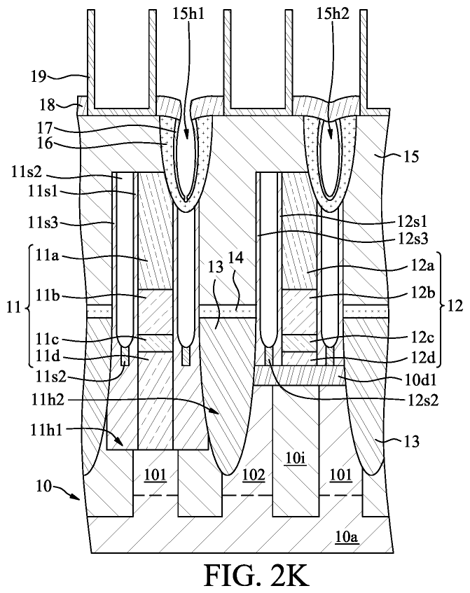

The recess region 15h1 may be exposed to air through the interlayer 18. For example, in the etching process in FIG. 2K, the interlayer 18 may be penetrated and a portion of the sealing layer 17 may also be etched away. The sealing layer 16 in the recess region 15h1 may be exposed to air through the sealing layer 17. For example, the sealing layer 16 in the recess region 15h1 may be partially covered by the sealing layer 17 and partially exposed to air.

The sealing layer 16 may be exposed to air in the recess region 15h1 and exposed to air in the spacer 11s2. The sealing layer 16 may separate the air in the recess region 15h1 from the air in the spacer 11s2.

The interlayer 18 may be disposed over the landing pad 15. The interlayer 18 may include, for example, silicon oxide (SiO₂), silicon nitride (Si₃N₄) and/or silicon oxynitride. The interlayer 18 may be a single layer or a multi-layer. The sealing layer 16 may contact the interlayer 18.

The bottom electrode (or the lower electrode) 19 may be disposed over the landing pad 15. The bottom electrode 19 may be vertically overlapped with the bit line structures 11 and 12. The bottom electrode 19 may be electrically connected to the storage node contact 13.

The bottom electrode 19 may include a doped semiconductor material (e.g., doped silicon), a metal (e.g., tungsten, titanium, and tantalum), a conductive metal nitride (e.g., titanium nitride, titanium aluminum nitride, titanium silicon nitride, tantalum nitride, tantalum aluminum nitride, tantalum silicon nitride, and tungsten nitride), a conductive metal oxide (e.g., iridium oxide), or other conductive materials.

In some embodiments, the sealing layer 16 may truncate the spacer 11s1 and contact (such as directly contact) the bit line capping pattern 11a of the bit line structure 11.

The bit line structure 12 may be spaced apart from (or separated from) the bit line structure 11 by the storage node contact 13. The bit line structure 12 may be disposed over the interlayer 10d1. The bit line structure 12 may be spaced apart from (or separated from) the substrate 10 by the interlayer 10d1.

The bit line structure 12 may include a bit line contact 12d and stacked patterns (such as a conductive pattern 12c, a conductive pattern 12b, and a bit line capping pattern 12a). The bit line structure 12 may include an insulating spacer structure. The insulating spacer structure may include spacers 12s1, 12s2, and 12s3 formed on both sidewalls of the bit line structure 12.

The spacer 12s2 may include an oxygen-containing material, such as silicon oxide (SiO₂). The spacer 12s2 may include an air spacer in which air is filled. In some embodiments, the spacer 12s2 may include a combination of an oxygen-containing material and an air spacer.

In some embodiments, an upper portion of the spacer 12s2 may contact the sealing layer 16. For example, the spacer 12s2 may be closed by or covered by the sealing layer 16.

The detailed descriptions of the bit line structure 12 may refer to detailed descriptions of the bit line structure 11 provided above, which will not be repeated for the sake of brevity.

In a conventional process, an air gap (such as the air gap defined by the sealing layer 16 and the sealing layer 17) may be formed to electrically insulate the neighboring bit line structures from their respective storage node contacts.

When the mold layer around the capacitor bottom electrode is partially removed through a wet etching process (such as the operation in FIG. 2K), the wet etch solution may penetrate the bottom of the air gap and erode the adjacent spacers and the storage node contacts. This erosion issue can degrade performance of the semiconductor device, and is a limiting factor that must be addressed to achieve further enhancements in semiconductor device integration.

The sealing layer (such as the sealing layer 16) is sufficiently resistant to, for example, a wet etch solution, to prevent over-etching and penetration of the bottom of the air gap. For example, the sealing layer can adequately perform its purpose as an etch stop layer in subsequent etching processes. Therefore, the erosion issue can be addressed. The performance and operational reliability of the semiconductor device can also be improved.

FIG. 1B is an enlarged view of a portion of a semiconductor device in accordance with some embodiments of the present disclosure. In some embodiments, the semiconductor device 1a may include an enlarged view in FIG. 1B.

The recess region 15h1 may be exposed to air through the interlayer 18. For example, in the etching process in FIG. 2K, the interlayer 18 may be penetrated. A portion of the sealing layer 17 and a portion of the sealing layer 16 may also be etched away. A surface of the sealing layer 16 in the recess region 15h1 may be exposed through the sealing layer 17 and partially etched.

FIGS. 2A, 2B, 2C, 2D, 2E, 2F, 2G, 2H, 2I, and 2K illustrate stages of a method of manufacturing a semiconductor device in accordance with some embodiments of the present disclosure. At least some of these figures have been simplified for a better understanding of the aspects of the present disclosure. In some embodiments, the semiconductor device 1a in FIG. 1A may be manufactured by the operations described below with respect to FIGS. 2A, 2B, 2C, 2D, 2E, 2F, 2G, 2H, 2I, and 2K.

As shown in FIG. 2A, the isolation region 10i may be formed through an STI (shallow trench isolation) process. For example, after a pad layer (not shown) is formed on the substrate 10, the pad layer and the substrate 10 may be etched using an isolation mask (not shown) to define an isolation trench. The isolation trench may be filled with a dielectric material, and accordingly, the isolation region 10i is formed.

The isolation trench may be filled with a dielectric material through a chemical vapor deposition (CVD) process. Also, a planarization process such as chemical-mechanical polishing (CMP) may be additionally performed.

The doped region 101 and two doped regions 102 may be formed in the active region 10a. The doped region 101 and two doped regions 102 may be spaced apart from one another by the isolation regions 10i.

One or more recess regions may be formed in the substrate 10. For example, the recess region 11h1 may be formed in the doped region 101. In some embodiments, the substrate 10 may be patterned to form one or more recess regions exposing the doped region 101. In some embodiments, the substrate 10 may be patterned to form one or more recess regions exposing the bit line contact region in the doped region 101, and the bit line contact region is configured to be electrically connected with a bit line structure.

In some embodiments, the recess regions may be arranged in either a honeycomb form or a zigzag form in a top view. In some embodiments, the recess regions may each have a circular shape or an elliptical shape.

The interlayer 10d1 may be disposed on the substrate 10. The interlayer 10d1 may be disposed on the top surface of the active region 10a. In some embodiments, the recess region 11h1 may be formed by an etching operation, such as an anisotropic etching operation. For example, the interlayer 10d1 may define the doped region 101 or the bit line contact region in the doped region 101.

A plurality of bit line structures (such as the bit line structures 11 and 12) may be formed over the substrate 10. The bit line structures may each overlap a plurality of the recess regions. For example, the bit line structure 11 may overlap the recess region 11h1.

The bit line structure 11 may include the bit line contact 11d for connecting the bit line contact region in the doped region 101. The bit line structure 12 may include the bit line contact 12d disposed over the interlayer 10d1. The bit line structures may each include a bit line contact, a conductive pattern, a conductive pattern, and a bit line capping pattern that are sequentially stacked.

In some embodiments, the bit line structure 11 may be formed by disposing the material of the bit line contact 11d over the interlayer 10d1 to fill the recess region 11h1, and disposing the materials of the conductive pattern 11c, the conductive pattern 11b, and the bit line capping pattern 11a sequentially. Then, the materials may be etched through a bit line mask pattern.

An insulating spacer structure may be formed on opposite sidewalls of the bit line structure 11. An insulating spacer structure may be formed on opposite sidewalls of the bit line structure 12.

A material of the spacer 11s1 may be formed on opposite sidewalls of the bit line structure 11. A material of the spacer 12s1 may be formed on opposite sidewalls of the bit line structure 12. In some embodiments, the spacers 11s1 and 12s1 may each include a nitrogen-containing material, such as silicon nitride (Si₃N₄). In some embodiments, the materials of the spacers 11s1 and 12s1 may be formed by any suitable process, such as atomic layer deposition (ALD).

A material of the spacer 11s2 may be formed on opposite sidewalls of the bit line structure 11. A material of the spacer 12s2 may be formed on opposite sidewalls of the bit line structure 12. In some embodiments, the spacers 11s2 and 12s2 may each include an oxygen-containing material, such as silicon oxide (SiO₂). In some embodiments, the materials of the spacers 11s2 and 12s2 may be formed by any suitable process, such as atomic layer deposition (ALD).

A material of the spacer 11s3 may be formed on opposite sidewalls of the bit line structure 11. A material of the spacer 12s3 may be formed on opposite sidewalls of the bit line structure 12. In some embodiments, the spacers 11s3 and 12s3 may each include a nitrogen-containing material, such as silicon nitride (Si₃N₄). In some embodiments, the materials of the spacers 11s3 and 12s3 may be formed by any suitable process, such as atomic layer deposition (ALD).

The recess region 11h2 may be formed in the substrate 10 to expose the doped region 102. A material of the storage node contact 13 may be disposed in the recess region 11h2. The material of the storage node contact 13 may be disposed adjacent to the bit line structure 11. A recessing process may be performed on the material of the storage node contact 13. The recessing process may be performed by a dry etch process, for example, an etch-back process.

Subsequently, the metal silicide film 14 may be formed on an exposed surface of the storage node contact 13. In some embodiments, the metal silicide film 14 may be formed by disposing a metal layer on an exposed surface of the storage node contact 13, and performing a thermal process.

Next, the landing pad 15 may be disposed over the metal silicide film 14. The landing pad 15 may fill in the space between the bit line structures (such as the bit line structures 11 and 12). In some embodiments, the landing pad 15 may be formed by any suitable process, such as chemical vapor deposition (CVD) or physical vapor deposition (PVD).

As shown in FIG. 2B, a portion of the bit line capping pattern 11a, a portion of the insulating spacer structure of the bit line structure 11, and a portion of the landing pad 15 may be removed through an etching process using a mask pattern. A top surface of the insulating spacer structure may be exposed during the etching process and the recess region 15h1 may be formed. The recess region 15h2 may be formed in the same etching process. After the etching process, the mask pattern may be removed.

As shown in FIG. 2C, a portion of the spacer 11s2 may be removed through an etching process using a chemical etchant (e.g., HF (hydrogen fluoride) vapor), and a pair of air gaps may be formed on opposite sidewalls of the bit line structure 11. A portion of the spacer 11s2 may remain on the bottom of the air gap.

A portion of the spacer 12s2 may be removed through an etching process using a chemical etchant (e.g., HF (hydrogen fluoride) vapor), and a pair of air gaps may be formed on opposite sidewalls of the bit line structure 12. A portion of the spacer 12s2 may remain on the bottom of the air gap.

As shown in FIG. 2D, the sealing layer 16 may be disposed over the landing pad 15 and in the recess regions 15h1 and 15h2.

In some embodiments, the sealing layer 16 may include a carbon-containing material, such as SiC (silicon carbide), SiOC (silicon oxycarbide), SiCN (silicon carbon nitride), and SiOCN (silicon oxycarbonitride). In some embodiments, the sealing layer 16 may be formed by any suitable process, such as low-pressure chemical vapor deposition (LPCVD), plasma enhanced-chemical vapor deposition (PECVD), atomic layer deposition (ALD), or physical vapor deposition (PVD), thermally grown, or chemically grown.

As shown in FIG. 2E, the sealing layer 17 may be disposed over the landing pad 15 and in the recess regions 15h1 and 15h2. In some embodiments, the sealing layer 17 may be formed by any suitable process, such as atomic layer deposition (ALD). The sealing layer 16 and the sealing layer 17 may define an air gap.

As shown in FIG. 2F, the sealing layers 16 and 17 may be removed by a planarization process such as chemical-mechanical polishing (CMP). The air gap may be exposed. The sealing layer 16 may be exposed.

As shown in FIG. 2G, the interlayer 18 may be disposed over the landing pad 15. The interlayer 18 may cover the recess regions 15h1 and 15h2. The interlayer 18 may cover the air gap defined by the sealing layers 16 and 17. The interlayer 18 may be formed by any suitable process, such as chemical vapor deposition (CVD) or physical vapor deposition (PVD).

As shown in FIG. 2H, the layers under the landing pad 15 are not shown for conciseness. A first mold layer 20 may be formed on the interlayer 18. The first mold layer 20 may include silicon oxide (SiO₂), undoped silica glass (USG), borosilica glass (BSG), phosphosilica glass (PSG), borophosphosilica glass (BPSG), tetraethyl orthosilicate (TEOS), plasma enhanced tetraethyl orthosilicate (PE-TEOS), and fluoride silicate glass (FSG), etc. The first mold layer 20 may include a single layer or a multi-layer. The first mold layer 20 may be formed by any suitable process, such as chemical vapor deposition (CVD) or physical vapor deposition (PVD).

The first supporting layer 21 may be formed on the first mold layer 20. The first supporting layer 21 may include silicon oxide (SiO₂), silicon nitride (Si₃N₄), or silicon oxynitride. The first supporting layer 21 may be formed by any suitable process, such as chemical vapor deposition (CVD) or physical vapor deposition (PVD).

The second mold layer 22 may be formed on the first supporting layer 21. The second mold layer 22 may include the same material as that of the first mold layer 20.

The second supporting layer 23 may be formed on the second mold layer 22. The second supporting layer 23 may include the same material as that of the first supporting layer 21.

As shown in FIG. 2I, the interlayer 18, the first mold layer 20, the first supporting layer 21, the second mold layer 22, and the second supporting layer 23 may be partially removed to form the contact holes 23h. The landing pad 15 may be exposed from the contact holes 23h.

As shown in FIG. 2J, the bottom electrodes 19 may be disposed within each of the contact holes 23h. The bottom electrodes 19 may be formed by any suitable process, such as chemical vapor deposition (CVD) or physical vapor deposition (PVD).

As shown in FIG. 2K, the first mold layer 20, the first supporting layer 21, the second mold layer 22, and the second supporting layer 23 may be removed to expose the interlayer 18.

The first mold layer 20, the first supporting layer 21, the second mold layer 22, and the second supporting layer 23 may be removed through an etching process, such as a wet etching process. The wet chemical etchant may include ammonium fluoride (NH₄F), hydrofluoric acid (HF), hydrochloric acid (HCl), ammonium hydroxide (NH₄OH), ammonium sulfide (NH₄)₂S and combinations thereof.

The recess region 15h1 may be exposed to air through the interlayer 18. For example, in the etching process in FIG. 2K, the interlayer 18 may be penetrated and a portion of the sealing layer 17 may also be etched away. The sealing layer 16 is sufficiently resistant to the wet etchant, to prevent over-etching and penetration of the bottom of the recess region 15h1.

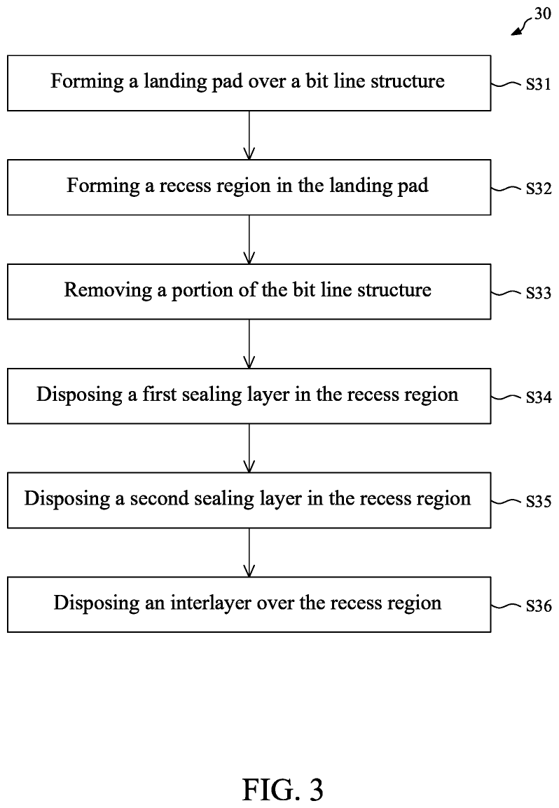

FIG. 3 illustrates a flow chart of a method 30 of manufacturing a semiconductor device in accordance with some embodiments of the present disclosure.

In some embodiments, the method 30 may include a step S31 of forming a landing pad over a bit line structure. For example, as shown in FIG. 2A, the landing pad 15 may be disposed over the bit line structure 11.

In some embodiments, the method 30 may include a step S32 of forming a recess region in the landing pad. For example, as shown in FIG. 2B, a portion of the bit line capping pattern 11a, a portion of the insulating spacer structure of the bit line structure 11, and a portion of the landing pad 15 may be removed through an etching process using a mask pattern. The recess region 15h1 may be formed.

In some embodiments, the method 30 may include a step S33 of removing a portion of the bit line structure. For example, as shown in FIG. 2C, a portion of the spacer 11s2 may be removed through an etching process using a chemical etchant (e.g., HF (hydrogen fluoride) vapor), and a pair of air gaps may be formed on opposite sidewalls of the bit line structure 11. A portion of the spacer 11s2 may remain on the bottom of the air gap.

In some embodiments, the method 30 may include a step S34 of disposing a first sealing layer in the recess region. For example, as shown in FIG. 2D, the sealing layer 16 may be disposed over the landing pad 15 and in the recess regions 15h1 and 15h2.

In some embodiments, the method 30 may include a step S35 of disposing a second sealing layer in the recess region. For example, as shown in FIG. 2E, the sealing layer 17 may be disposed over the landing pad 15 and in the recess regions 15h1 and 15h2.

In some embodiments, the method 30 may include a step S36 of disposing an interlayer over the recess region. For example, as shown in FIG. 2G, the interlayer 18 may be disposed over the landing pad 15. The interlayer 18 may cover the recess regions 15h1 and 15h2.

One aspect of the present disclosure provides a semiconductor device. The semiconductor device includes a substrate and a bit line structure disposed over the substrate. The bit line structure includes an insulating spacer structure defining an air spacer. The semiconductor device also includes a sealing layer disposed over the insulating spacer structure to cover the air spacer. The sealing layer includes a carbon-containing material.

Another aspect of the present disclosure provides a semiconductor device. The semiconductor device includes a substrate, a bit line structure disposed over the substrate, and a landing pad disposed over the bit line structure and having a recess region. The semiconductor device also includes a first sealing layer disposed in the recess region. The first sealing layer includes a carbon-containing material.

Another aspect of the present disclosure provides a method of manufacturing a semiconductor device. The method includes forming a landing pad over a bit line structure and forming a recess region in the landing pad. The method also includes removing a portion of the bit line structure and disposing a first sealing layer in the recess region.

The sealing layer is sufficiently resistant to, for example, a wet etch solution, to prevent over-etching and penetration of the bottom of the air gap. For example, the sealing layer can adequately perform its purpose as an etch stop layer in subsequent etching processes. Therefore, the erosion issue can be addressed. The performance and operational reliability of the semiconductor device can also be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a substrate;
a bit line structure disposed over the substrate, wherein the bit line structure includes an insulating spacer structure defining an air spacer; and
a sealing layer disposed over the insulating spacer structure to cover the air spacer, wherein the sealing layer includes a carbon-containing material.

2. The semiconductor device of claim 1, wherein the insulating spacer structure includes a first spacer, a second spacer, and a third spacer, and wherein the second spacer defines the air spacer.

3. The semiconductor device of claim 2, wherein the first spacer and the third spacer are connected.

4. The semiconductor device of claim 3, wherein the first spacer and the third spacer include a nitrogen-containing material.

5. The semiconductor device of claim 2, wherein the second spacer includes an oxygen-containing material, and the air spacer is defined over the oxygen-containing material.

6. The semiconductor device of claim 1, wherein the sealing layer contacts the bit line structure.

7. The semiconductor device of claim 1, further comprising:
a landing pad disposed over the bit line structure and having a recess region, wherein the sealing layer is disposed in the recess region.

8. The semiconductor device of claim 7, wherein the sealing layer is exposed to air in the recess region and exposed to air in the air spacer.

9. The semiconductor device of claim 8, wherein the sealing layer in the recess region is partially etched.

10. The semiconductor device of claim 8, wherein the sealing layer separated the air in the recess region from the air in the air spacer.

11. The semiconductor device of claim 1, wherein the insulating spacer structure is disposed between the bit line structure and a storage node contact.
